(19) United States
(12) Patent Application Publication
(10) Pub. No.: US 2025/0266241 A1
(43) Pub. Date: Aug. 21, 2025

(54) MULTI-BEAM CHARGED PARTICLE IMAGING SYSTEM WITH REDUCED CHARGING EFFECTS

(71) Applicant: Carl Zeiss MultiSEM GmbH, Oberkochen (DE)

(72) Inventor: Stefan SCHUBERT, Oberkochen (DE)

(21) Appl. No.: 19/202,694

(22) Filed: May 8, 2025

Related U.S. Application Data
(63) Continuation of application No. PCT/EP2023/025443, filed on Oct. 24, 2023.

(30) Foreign Application Priority Data
Nov. 10, 2022 (DE) 10 2022 211 883.9

(51) Int. Cl. H01J 37/317; H01J 37/02; H01J 37/22; H01J 37/24; H01J 37/26; H01J 37/28

(52) U.S. Cl. CPC H01J 37/3177; H01J 37/026; H01J 37/222; H01J 37/241; H01J 37/265; H01J 37/28; H01J 2237/0453; H01J 2237/24535

(57) ABSTRACT

A method for imaging of semiconductor samples with reduced charging effects and a multi-beam charged particle beam system configured for imaging of semiconductor samples with reduced charging effects comprises adjusting the kinetic energy of primary charged particles to a low energy transition energy, where charging of a material composition is minimized. The system and method include for example a monitoring system and optimization of the kinetic energy to minimize charging effects.

### CROSS-REFERENCE TO RELATED APPLICATIONS

The present application is a continuation of, and claims benefit under 35 USC 120 to, international application No. PCT/EP2023/025443, filed Oct. 24, 2023, which claims benefit under 35 USC 119 of German Application No. 10 2022 211 883.9, filed Nov. 10, 2022. The entire disclosure of each of these applications is incorporated by reference herein.

### FIELD

The present disclosure relates to a multi-beam charged particle imaging system and an improved method of operation of a multi-beam charged particle imaging system. More particularly, the present disclosure relates to a control unit of a multi-beam charged particle imaging system and a method for imaging of semiconductor samples with reduced charging effects.

### BACKGROUND

With the continuous development of ever smaller and ever more complex microstructures such as semiconductor components, it is desirable to develop and optimize planar production techniques and inspection systems for producing and inspecting small dimensions of the microstructures. By way of example, the development and production of the semiconductor components involves high resolution metrology tools with high throughput. The planar production techniques involve process monitoring and process optimization for a reliable production with a high throughput. Moreover, there have been recent demands for an analysis of semiconductor wafers for reverse engineering and for a customer-specific, individual configuration of semiconductor components. Therefore, there is a desire for inspection mechanism which can be used with a high throughput for examining the microstructures on wafers with great accuracy.

Recently, multi-beam scanning electron microscopes have been introduced to support development and manufacturing of micro-electronic semiconductor components. By way of example, a multi-beam scanning electron microscope is disclosed in U.S. Pat. No. 7,244,949 B2 and in US 2019/0355544 A1. In the case of a multi-beam charged particle microscope or MSEM, a sample is irradiated simultaneously with a plurality of individual electron beams, which are arranged in a field or raster. By way of example, J=4 to J=10,000 individual electron beams can be provided as primary radiation, with each individual electron beam being separated from an adjacent individual electron beam by a pitch of 1 to 200 micrometers (μm). By way of example, an MSEM has approximately J=100 separated individual electron beams (“beamlets”), which for example are arranged in a hexagonal raster, with the individual electron beams being separated by a pitch of approximately 10 μm. The plurality of J individual charged particle beams (primary beams) are focused on a surface of a sample to be examined by way of a common objective lens. By way of example, the sample can be a semiconductor wafer which is accommodated via a wafer chuck that is assembled on a movable stage. During the illumination of the wafer surface with the primary individual particle beams, interaction products, for example secondary electrons or backscattered electrons, emanate from the surface of the wafer. Their start points correspond to those locations on the sample on which the plurality of J primary individual particle beams are focused in each case. The amount and the energy of the interaction products generally depend on the material composition and the topography of the wafer surface. The interaction products form a plurality of secondary individual particle beams (secondary beams), which are collected by the common objective lens, and which are directed by a secondary electron optical imaging system at a detector arranged in an image plane. The detector comprises a plurality of detection regions, each of which comprises at least one detection element, and the detector measures an intensity distribution for each of the J secondary individual particle beams. An example of such a detector is shown in U.S. Pat. No. 10,163,603 BB. The plurality of secondary beamlets is focused by the secondary electron optical imaging system and a plurality of focus points of the secondary beamlets is formed on an image plane, in which the detector is arranged. The detector generally comprises a plurality of detection elements. The number of detection elements is at least as high as the number of beamlets, such that each of the secondary beamlets is detected by at least one detection element. Typically, each secondary beamlet is assigned to a set of detection elements, by which the intensity of one corresponding secondary beamlet is detected. In an example, each secondary beamlet is assigned to a set of detection elements, wherein each set of detection elements comprises at least one, for example, four, nine or more individual detection elements. A digital image of an image field of for example 100 μm×100 μm is obtained in the process.

However, the raster configuration of the focus spots of the secondary electron beamlets can be subject to changes or drifts arising from charging effects of the sample. Charging effects can have a significant influence on secondary electrons generated in interaction volumes close to the surface of a sample. For example, the kinetic energy of excited secondary electrons generally depends on a charging of the sample. However, local charging can also generate image distortion and even an image shift. Therefore, the signal strength of collected secondary electrons can be reduced or cross talk can be increased. Cross talk is generally the effect of detection of unwanted secondary electrons by a set of detection elements, wherein unwanted secondary electrons are for example secondary electrons from other secondary electron beamlets which are not assigned to the respective set of detection elements.

In the case of scanning electron microscopes for certain wafer inspection applications, it is generally desirable to keep the imaging conditions stable such that the imaging can be carried out with great reliability, great throughput, high resolution and high repeatability.

Voltage contrast methods on the other hand utilize charging effects for defect detection. Such methods, as for example described in U.S. Pat. No. 6,563,114 B1, rely on charging effects, achieved for example with primary electrons with high kinetic energy. U.S. Pat. No. 6,563,114 B1 shows a wide-field electron beam inspection system for wafer inspection, using a primary electron beam of large rectangular size with high kinetic energy to excite secondary electron and generate charged areas. Different charging of defects is utilized to detect the defects. The induced distortion or an image shift and their negative effects for example for metrology applications are not addressed.

### SUMMARY

The disclosure seeks to provide an improved multi-beam charged particle imaging system and an improved method of operation of such a system. The method and system can configured to reduce image distortion or image shifts and which is configured for the desired high-resolution of recent inspection tasks. The method and system can be configured to reduce charging effects during the inspection of semiconductor samples.

In an aspect, the disclosure provides a multi-beam charged particle imaging system which comprises a mechanism for generating a plurality of primary charged particle beamlets. The multi-beam charged particle imaging system comprises an object irradiation system for focusing the plurality of primary charged particle beamlets on a surface of an object at a plurality of irradiation positions. During use, at each irradiation position, secondary charged particles are generated, from which a plurality of secondary beamlets is formed.

The multi-beam charged particle imaging system comprises a secondary electron imaging system for focusing the plurality of secondary beamlets and for forming a plurality of focus points of the secondary beamlets in an image plane. The multi-beam charged particle imaging system further comprises a detector, arranged in the image plane. The multi-beam charged particle imaging system further comprises a controller configured to operate the multi-beam charged particle imaging system with reduced charging effects at a semiconductor sample. In an example, a multi-beam charged particle beam system comprises a primary beam illumination system comprising a primary beamlet generation unit and an objective lens and a sample platform connected to a sample voltage supply. The sample platform is configured to hold and contact during use a wafer and to provide a sample voltage VS to a wafer. The multi-beam charged particle beam system further comprises an electrode, which can be formed as a separate electrode or an exit aperture of a beam tube. The electrode is connected to a voltage supply. The control unit is configured to control the sample voltage supply to provide a voltage VS to the sample platform to affect a deceleration of primary charged particles before impacting on a surface of a wafer to a low energy transition energy ELT of a material composition of a wafer. At the low energy transition energy ELT charging of the material composition of the wafer is minimized. In an example, the low energy transition energy ELT is predetermined and stored in a memory of the control unit. In an example, a material composition of a wafer is predetermined according to for example CAD information of the wafer, and the low energy transition energy ELT is determined according to a simulation or a previously determined low energy transition energy ELT for the material composition.

In an example, the multi-beam charged particle beam system further comprises a monitoring system configured to monitor a plurality of focus spots of a plurality of secondary electron beamlets. A monitoring control unit can be configured to determine during operation a displacement or scale error of the raster of focus spots of secondary electron beamlets obtained with the monitoring system. Thereby, low energy transition energy ELT for the material composition can be determined via a charging effect present at the material composition with an irradiation with primary charged particles with a kinetic energy deviating from the low energy transition energy ELT.

In an example, the multi-beam charged particle beam system comprises an exit aperture of a beam tube connected to a first voltage supply and an electrode connected to a second voltage supply, configured to generate a first, constant deceleration field and a second, variable deceleration or extraction field between the objective lens and the surface. Thereby, a kinetic energy of primary charged particles can be adjusted even more precisely to a low energy transition energy ELT for a material composition.

In an aspect, the disclosure provides a method of operating a multi-beam charged particle beam system with reduced charging effects of a sample is disclosed. The method comprises loading a sample on a sample platform of a sample stage of the multi-beam charged particle beam system. The method comprises setting a first kinetic energy of the plurality of primary charged particle beamlets before reaching a surface of the sample by providing a first voltage via a voltage supply unit to the sample platform, thereby generating an extraction field between an objective lens of the multi-beam charged particle beam system and the sample surface. The method comprises starting an image acquisition of a surface segment of the sample surface and monitoring a plurality of focus spots of secondary electron beamlets, the secondary electron beamlets being generated at a plurality of focus points of the plurality of primary charged particle beamlets at the sample surface. The method further comprises determining at least one of a displacement or a scale error of the plurality of focus spots of the secondary electron beamlets and determining a second kinetic energy of the plurality of primary charged particle beamlets based on the displacement or the scale error. The method further comprises setting the second kinetic energy by providing a second voltage to the sample platform. With the method, a charging effect of the sample is minimized.

In an example, a kinetic energy of the plurality of primary charged particle beamlets before reaching the sample surface corresponds to a low energy transition energy ELT of a first material composition at the sample surface. In an example, the kinetic energy of the plurality of primary charged particle beamlets before reaching the sample surface is set to a low energy of below 800 eV, for example below 500 eV, below 300 eV or even less. For example, the kinetic energy of the plurality of primary charged particle beamlets before reaching the sample surface is set between 90 eV and 250 eV.

In an example, the first or second kinetic energy of the plurality of primary charged particle beamlets before reaching the sample surface corresponds to a maximum value of a first low energy transition energy ELT1 of a first material composition and a second low energy transition energy ELT2 of a second material composition at the sample surface. For example, the first or second kinetic energy of the plurality of primary charged particle beamlets before reaching the sample surface is set to the first low energy transition energy ELT1 of the first material composition with the second low energy transition energy ELT2 of the second material composition being smaller compared to the first low energy transition energy ELT1. In an example, the method further comprises individually reducing at least a beam current I of at least one of the plurality of primary charged-particle beamlets, for example a current of a primary charged-particle beamlet configured for image acquisition of a surface segment comprising the second material composition is reduced. Thereby, a charging effect of the second material composition can be reduced.

In an example, the second kinetic energy is determined from the displacement error and a line scanning direction perpendicular to the scanning lines during image acquisition. For example, from a direction of the displacement error and the line scanning direction, a negative charging effect is determined, and a second kinetic energy is increased relative to the first kinetic energy. For example, from a direction of the displacement error and the line scanning direction, a positive charging effect is determined, and a second kinetic energy is reduced relative to the first kinetic energy.

In an example, the method comprises repeating the monitoring and determining of least one of a displacement or a scale error of the plurality of focus spots of the secondary electron beamlets during an image acquisition. The method comprises repeating the determining of an optimized kinetic energy of the plurality of primary charged particle beamlets configured to minimize a charging effect of the sample. The optimized kinetic energy is stored in a memory for repeated use, for example at a sample or an inspection site with similar material composition.

In an example, the first kinetic energy of the plurality of primary charged particle beamlets before reaching the sample surface is set according to a first material composition of the sample surface. The first material composition can be determined from prior knowledge, for example CAD data of a wafer. In an example, the first kinetic energy of the plurality of primary charged particle beamlets before reaching the sample surface is set according to a previously determined kinetic energy stored in a memory.

In an aspect, the disclosure provides a method of wafer inspection with a multi-beam charged particle beam system. The method comprises loading a wafer on a sample platform of a sample stage of a multi-beam charged particle beam system and setting a first kinetic energy of the plurality of primary charged particle beamlets before reaching the wafer surface by adjusting an extraction field between an objective lens of the multi-beam charged particle beam system and the wafer surface, wherein the first kinetic energy is set to a first low energy transition energy ELT of a first material composition comprised within a surface segment of the wafer surface. The method further comprises starting an image acquisition of the surface segment of the wafer surface. The first kinetic energy of the plurality of primary charged particle beamlets before reaching the wafer surface is for example set to a low energy of below 800 electronvolts (eV), for example below 500 eV, below 300 eV or even less, for example between 90 eV and 250 eV. In an example, the first kinetic energy of the plurality of primary charged particle beamlets is set according to a previously determined kinetic energy stored in a memory. Different low energy transition energies ELTs of different material compositions typically comprised within wafers can be stored in a memory.

In an aspect, the disclosure provides a multi-beam charged particle beam system which comprises a primary beam illumination system, comprising a primary beamlet generation unit and an objective lens. The multi-beam charged particle beam system comprises a sample platform connected to a sample voltage supply configured to hold and contact a wafer and to provide a sample voltage VS a wafer. The multi-beam charged particle beam system comprises at least an electrode selected from a group comprising an exit aperture of a beam tube and an electrode connected to a voltage supply. The multi-beam charged particle beam system comprises a control unit with a memory comprising software instructions and a control processor configured to execute the software instructions to perform a method according to the second embodiment. In an example, the multi-beam charged particle beam system further comprises a monitoring system configured to monitor a plurality of focus spots of a plurality of secondary electron beamlets, and a monitoring control unit configured to determine during operation a displacement or scale error of the raster of focus spots of secondary electron beamlets obtained with the monitoring system. With the system and the method according to the disclosure, a charging effect of a material composition at a surface of a wafer can be reduced. The reduction can be achieved by setting the kinetic energy of primary charged particles to a transition energy, where a charging balance between incident beam current of primary charged particles and exiting secondary electrons and backscattered electrons is achieved. To maintain a high resolution, the low energy transition energy ELT is selected, which can be below 800 eV or even less, for example below 500 eV, or below 300 eV. For example, for typical material compositions of semiconductor wafers such as comprising copper (Cu), tungsten (W), silicon (SI), aluminum (Al) or silicon dioxide (SiO₂), a kinetic energy of primary electrons is optionally between 90 eV and 250 eV. In a situation with more than one material compositions within the large image field of a multi-beam charged particle beam system, the maximum value of the low energy transition energies ELT of the material compositions is selected. With the correspondingly strong extraction field, secondary electrons of low kinetic energy are extracted from the sample surface from each surface segment with different material compositions, and a low noise level of is achieved during image acquisition. Thereby, it is even possible to reduce individual beam currents to further reduce residual charging effects.

In the context of the disclosure, a raster configuration is an arrangement of elements (here, focus positions of primary or secondary beamlets) in a regular raster grid, for example a hexagonal raster grid, at predefined relative distances between the plurality of elements. The absolute size or scale and the rotation of the raster configuration can however be different at different positions within the multi-beam charged particle imaging system. Typical raster configurations comprise for example more than 60, more than 90 or even more than 300 primary beamlets, arranged in a hexagonal or rectangular raster. Other raster configurations are circular raster configurations, in which a plurality of beamlets is arranged on at least one circular ring.

The disclosure is not restricted to the specific embodiments and examples, but variations of the embodiments are also possible. Although in general reference is made to a wafer as an object, the disclosure is also applicable to other objects as used in semiconductor manufacturing. By way of example, the object can also be a mask, for example a mask for EUV lithography, rather than a semiconductor wafer. In contrast to semiconductor wafers, such masks are generally rectangular and have a significantly greater thickness. The disclosure is however not limited to objects as used in semiconductor manufacturing, but is also applicable to general objects, including for example mineral probes or tissue. The disclosure is further described at the example of a multi-beam system having a plurality of primary electron beamlets, but other charged particles, for example helium ions, may also be used.

The described embodiments of the disclosure can be combined with one another in full or in part, provided that no technical contradictions arise as a result. It is self-evident that a person skilled in the art considers obvious variations of the exemplary embodiments to be possible and not excluded in the description.

### BRIEF DESCRIPTION OF THE DRAWINGS

The disclosure will be understood even better with reference to the accompanying figures, in which:

FIG. 1 shows a multi-beam charged particle beam system according to the first embodiment and second embodiment;

FIGS. 2A-2D are illustrations of the raster configurations at the multi-beam forming unit, the object plane, the image plane, and the sets of detection elements;

FIG. 3 illustrates an example of a detector for secondary electron beamlet;

FIGS. 4A-4B illustrate a set of detection elements comprising a plurality of individual detection elements;

FIG. 5 illustrates example of a residual charging of different material compositions;

FIGS. 6A-6C illustrate a charging of a surface during image acquisition;

FIGS. 7A-7C illustrate an example of the raster of secondary electron beam spots on the detector with a charging sample;

FIG. 8 illustrates an example of a primary beamlet generation unit;

FIG. 9 illustrates a detail of an example of a primary beamlet generation unit;

FIGS. 10A-10B illustrate an example of raster configuration of secondary electron beam spots on detector elements;

FIGS. 11A-11B illustrate an example of monitoring signal of scanned secondary electron beam spots;

FIG. 12 illustrates a method according to an embodiment;

FIG. 13 illustrates some details of a multi-beam charged particle beam system according to the first embodiment and second embodiment;

FIG. 14 illustrates the extraction of secondary electrons with the extraction field; and

FIG. 15 illustrates at an example the effect of a sample charging during image acquisition

### DETAILED DESCRIPTION

Below, the same reference signs denote the same features, even if these are not explicitly mentioned in the text.

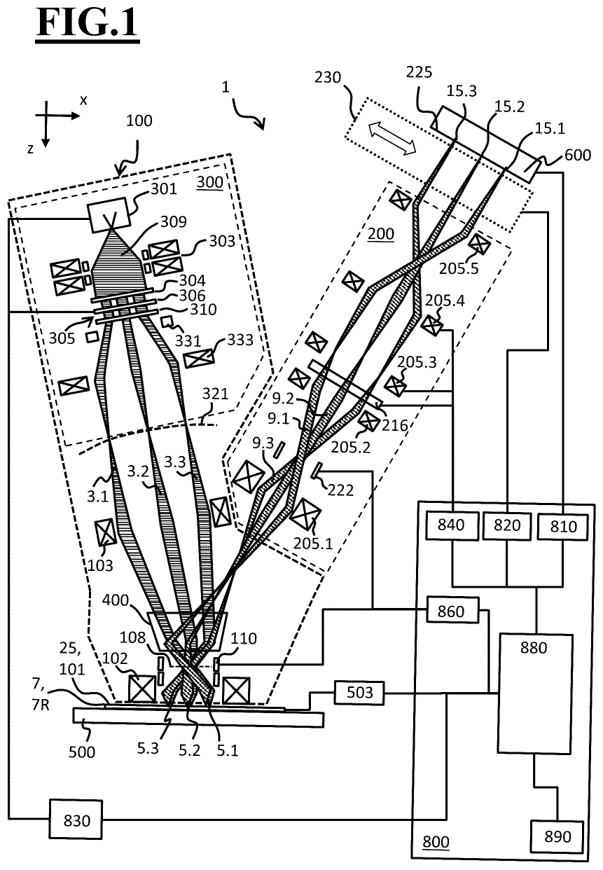

FIG. 1 is a schematic illustration of a multi-beam charged particle imaging system 1 (in short also multi-beam system 1) according to the first embodiment. The multi-beam system 1 uses a plurality of charged particle beams for forming an image of an object 7. The multi-beam system 1 generates a plurality of J primary particle beams 3 which strike the object 7 to be examined in order to generate interaction products, e.g. secondary electrons, which emanate from the object 7 and are subsequently detected. The multi-beam system 1 is of the scanning electron microscope (SEM) type, which uses a plurality of primary electron beams 3 which are incident on a surface of the object 7 at a plurality of locations and generate there a plurality of primary electron beam focus spots 5, that are spatially separated from one another. The object 7 to be examined can be of any desired type, e.g., a semiconductor wafer or a semiconductor mask, and can comprise an arrangement of miniaturized elements. The surface 25 of the object 7 is arranged in an object plane 101 of an objective lens 102 of an illumination system 100. The object 7 can be a wafer or a semiconductor mask or a reference object 7R with for example a regular microscopic pattern structure 27 (not shown).

A diameter of the minimal beam spots or focus spots 5 shaped in the object plane 101 can be small. Exemplary values of this diameter are below four nanometers, for example three nanometers (nm) or less. The focusing of the primary charged particle beamlets 3 for shaping the focus spots 5 is carried out by the objective lens system 102. In this case, the objective lens system 102 can comprise a magnetic immersion lens. Further examples of focusing mechanisms are described in the German patent DE 102020125534 B3, the entire content of which is herewith incorporated in the disclosure.

The plurality of focus spots 5 of the primary beams form a regular raster arrangement of incidence locations, which are formed in the object plane 101. The number J of beamlets primary beamlets may be five, twenty-five, or more. In practice, the number of beamlets J, and hence the number of incidence locations or focus spots 5, can be chosen to be significantly greater, such as, for example, J=10×10, J=20×30 or J=100×100. Exemplary values of the pitch P2 between the incidence locations are 1 micrometer, 10 micrometers, or more, for example 40 micrometers. For sake of simplicity, only three primary beamlets 3.1, 3.2 and 3.3 with corresponding focus points 5.1, 5.2 and 5.3 are shown in FIG. 1.

The primary particles 3 striking the object 7 generate interaction products, e.g. secondary electrons, back-scattered electrons, which emanate from the surface of the object 7, or primary particles that have experienced a reversal of movement for other reasons. The interaction products emanating from the surface of the object 7 are shaped by the objective lens 102 to form secondary electron beamlets 9. For sake of simplicity, through the disclosure, all the interaction products are collectively described as secondary electrons, forming secondary electron beamlets 9.

The multi-beam system 1 provides a detection beam path for guiding the plurality of secondary particle beamlets 9 to a secondary electron imaging system 200. The secondary electron imaging system 200 comprises several electron-optical lenses 205.1 to 205.5 for directing the secondary particle beams 9 towards a spatially resolving particle detector 600. The detector 600 is arranged in the image plane 225. The detector 600 comprises a plurality of detection elements. Detection elements can for example be diodes such as PM Ds, or CM OS detection elements, provided with electron-to-light conversion elements, or can be formed as direct electron detection elements.

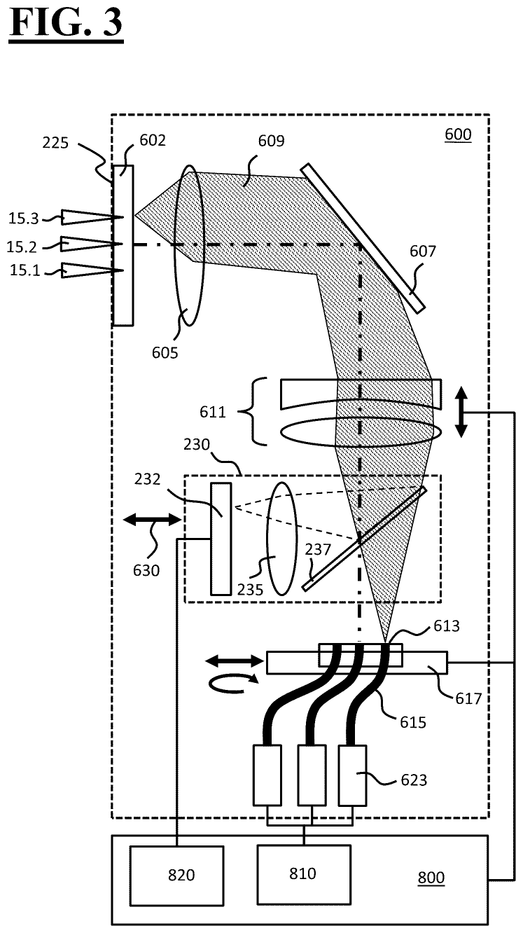

In an example, the detector 600 comprises an electron-to-light conversion element, such as a scintillator plate, by which secondary electrons are converted into light, and a plurality of light detection elements. The combination of the electron-to-light conversion element and the plurality of light detection elements hereby form together a plurality of electron detection elements. A further example of a detector is described below at the example of FIG. 3.

The imaging with the secondary electron imaging system 200 is strongly magnifying such that both the raster pitch of the primary beams on the wafer surface and the size and shape of focal points of the primary beams are imaged in much magnified fashion. By way of example, a magnification is between 100× and 300× such that one nm on the wafer surface is imaged enlarged to between 100 nm and 300 nm. In an example, an image field of a multi-beam system with for example 100 μm diameter is enlarged to approximately 30 mm.

The primary particle beams 3 are generated in a beam generation apparatus 300 comprising at least one particle source 301 (e.g. an electron source), at least one collimation lens 303, a multi-aperture arrangement 305 and a first field lens 331 and a second field lens 333. The particle source 301 generates at least one diverging particle beam 309, which is at least substantially collimated by the at least one collimation lens 303, and which illuminates the multi-aperture arrangement 305. The multi-aperture arrangement 305 comprises least one first multi-aperture or filter plate 304, which has a plurality of J openings formed therein in a first raster arrangement. Particles of the illuminating particle beam 309 pass through the J apertures or openings of the first multi-aperture plate 304 and form the plurality J of primary beamlets 3. Particles of the illuminating beam 309 which strike the first aperture plate 304 are absorbed by the latter and do not contribute to the formation of the primary beamlets 3. A multi-aperture arrangement 305 usually has at least a further multi-aperture plate 306, for example a lens array, a stigmator array or an array of deflection elements.

Together with the field lens 331 and a second field lens 333, the multi-aperture arrangement 305 focuses each of the primary beamlets 3 in such a way that focal points are formed in an intermediate image surface 321. Alternatively, the beam foci and the intermediate image surface 321 can be virtual. The intermediate image surface 321 can be curved to pre-compensate a field curvature of the imaging system arranged downstream of the intermediate image surface 321.

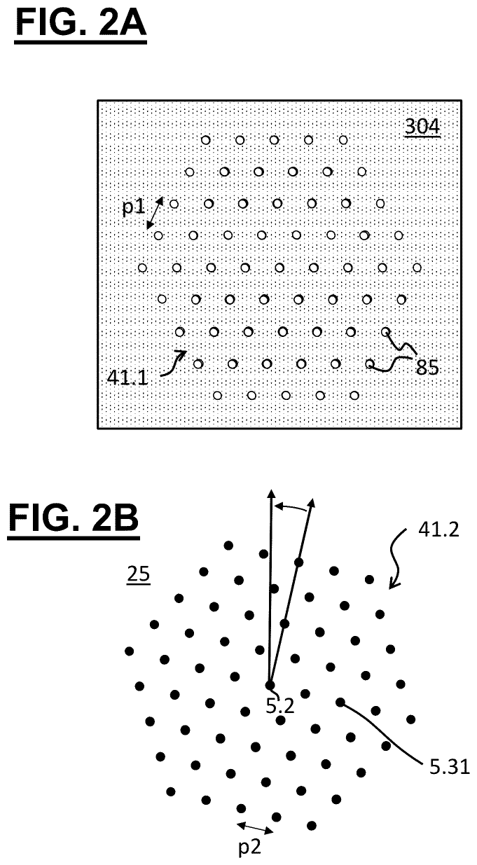

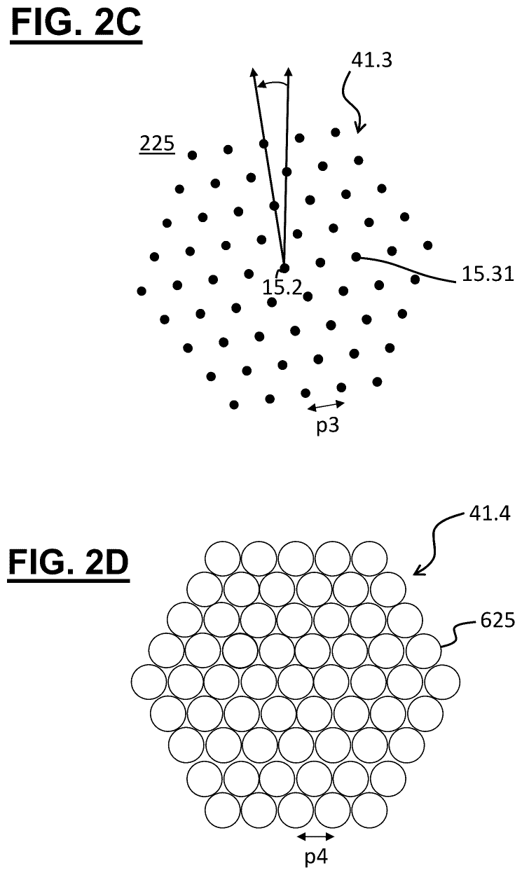

The at least one field lens 103 and the objective lens 102 provide a first imaging particle optical unit for imaging the surface 321, in which the beam foci are formed, onto the object plane 101 such that a second raster configuration of focus spots 5 of the primary beamlets is formed there. Typically, the surface 25 of the object 7 is arranged in the object plane 101, and the focal points 5 are correspondingly formed on the object surface 25 (see also FIG. 2B). The plurality of primary beamlets 3 form a crossover point 108, in the vicinity of which a first scanning deflector 110 is arranged. The first scanning deflector 110 is used to deflect the plurality of primary beamlets 3 collectively and synchronously such that the plurality of focus spots 5 are moved simultaneously over the surface 25 of the object 7. The first scanning deflector 110 is driven by a scanning control unit 860 such that in an inspection mode of operation, a plurality of two-dimensional image data of the surface is acquired. Additionally, the multi-beam system 1 can comprise further static deflectors configured to adjust the position of the plurality of the primary beamlets 3.

The objective lens 102 and the projection lenses 205 provide a secondary electron imaging system 200 for imaging the object plane 101 onto the detection plane 225. The objective lens 102 is thus a lens or a lens system that is part of both the first and the second particle optical unit, while the field lenses 103, 331 and 333 belong only to the first particle optical unit 100, and the projection lenses 205 belongs only to the secondary electron imaging system 200.

A beam divider 400 is arranged in the beam path of the first particle optical unit 100 between the field lens 103 and the objective lens system 102. The beam divider 400 is also part of the second optical unit in the beam path between the objective lens system 102 and the projection lenses 205.

The first deflection scanner 110 is arranged in a primary electron beam path or in a joint electron beam path. In the example shown in FIG. 1, the secondary electron beamlets 9 transmit during use the first deflection scanner 110 in opposite direction and the scanning movement of the secondary beamlets 9 is partially compensated. The secondary electrons have typically a different kinetic energy compared to the primary electrons. Therefore, the scanning movement of the moving irradiation positions is only partially compensated. To fully compensate the scanning movement of the secondary electron beamlets 9, the second deflection scanner 222 is arranged in the secondary electron beam path. The secondary electron imaging system 200 comprises the second, collective beam deflector 222 which is arranged in the vicinity of a crossover point of the secondary electron beamlets 9. The second, collective beam deflector 222 is operated synchronously with the first beam deflector 110 and compensates during use a beam deflection of the secondary electron beamlets 9 such that the focus points 15 of the secondary beamlets 9 remain at constant position on the detection plane 225. Thereby, each focus points 15 of each individual secondary beamlet 9 is kept within the area of a set of detection elements, which is assigned to the individual secondary beamlet 9.

The secondary electron imaging system 200 comprises electron-optical lenses 205.1 to 205.5 to adjust a focus plane of the focus spots 15 of the secondary electron beamlets 9. The electron-optical lenses 205.1 to 205.5 are shown as magneto-optical elements but are not limited to magneto-optical elements and can comprise also electro-static lens elements or stigmators. With the electron-optical lenses 205.1 to 205.5, the focus spots 15 of the secondary electron beamlets 9 can be focused into the image plane 225 of the secondary electron imaging system 200. The secondary electron imaging system 200 comprises a plurality of further components, for example at least one of a multi-aperture array element, a deflector or an exchangeable aperture stop. Together with the objective lens 102, the lenses serve to focus the secondary beams 9 on the spatially resolving detector 600 and, in the process, compensate the imaging scale and the twist of the plurality of secondary electron beamlets 9 as a result of a magnetic lens such that a third raster arrangement of the focal points 15 of the plurality of secondary electron beamlets 9 remains constant on the detector plane 225. For example, a first and second magnetic lenses 205.4 and 205.5 are designed in reversed order to one another and have oppositely directed magnetic fields. A Larmor rotation of the secondary electron beamlets 9 can be compensated by suitably driving the magnetic lenses 205.4 and 205.5. The secondary electron imaging system 200 has further correction elements available, for example a multi-aperture plate 216.

Further information relating to such multi-beam particle beam systems and components used therein, such as, for instance, particle sources, multi-aperture plate and lenses, can be obtained from the international patent applications WO 2005/024881, WO 2007/028595, WO 2007/028596, WO 2011/124352 and WO 2007/060017 and the German patent applications having the publication numbers DE 10 2013 016 113 A1 and DE 10 2013 014 976 A1, the disclosure of which in the full scope thereof is incorporated by reference in the present application.

The multi-beam charged particle imaging system 1 furthermore comprises a control system 800 configured both for controlling the individual particle optical components of the multiple particle beam system and for evaluating and analyzing the signals obtained by the detector 600. In this case, the control or controller system 800 can be constructed from a plurality of individual electronic computers or electronic components. By way of example, the control unit 800 comprises a control processor 880, a control module 840 for the control of the electron-optical elements of the secondary electron imaging system 200 and a control module 830 for the control of the electron-optical elements of the primary beamlet generation unit. The control unit 800 is further connected to a control module 503 for supplying a voltage to the sample 7, the voltage also being referred to as extraction voltage. Thereby, during use, an extraction field is generated between the objective 102 and the surface 25 of the object 7. During use, the extraction field decelerates the primary charged particles of the primary beamlets 3 before the sample surface 25 is reached and generates an additional focusing effect on the plurality of primary beamlets 3. At the same time, the extraction field serves during use to accelerate the secondary particles out of the surface 25 of the object 7.

Further, the control unit 800 comprises the scanning control module 860. During an inspection mode of operation, a plurality of focus points 15 of secondary electron beamlets is formed in the detection plane 225, and a plurality of signals is recorded during scanning operation of the primary beamlets 3 over the surface 25 of the sample 7. The detector 600 comprises a plurality of sets of detection elements with one set of detection elements for each secondary electron beamlet 9. During use, each set of detection elements is configured to record the intensity signal of the assigned secondary electron beamlet 9. The plurality of intensity signals for the plurality of secondary electron beamlets 9 is transferred to the image data acquisition unit 810, where the image data is processed and stored in memory 890. The sets of detection elements are arranged in a fourth raster configuration. The setup of the secondary electron optical imaging system 200, the detector 600, and the assignment of the sets of detection elements to the focus spots 15 of the secondary electron beamlets 9 is initially determined and stored in the memory 890 of the control unit 800 of the multi-beam charged particle imaging system 1.

According to the example of FIG. 1, the multi-beam charged particle imaging system 1 further comprises a retractable monitoring system 230, which can be inserted into the secondary electron beam path in front of the detection plane 225. The monitoring system 230 comprises further imaging elements and a high-resolution detector, comprising a large number of detection elements. The monitoring system 230 is connected to a monitoring control unit 820.

A multi-beam charged particle imaging system 1 according to the first embodiment comprise a mechanism for generating a plurality of primary charged particle beamlets 3, which are arranged in a first raster configuration. An example of the first raster configuration 41.1 is illustrated in FIG. 2A. FIG. 2A shows the first multi aperture plate 304 with a plurality of apertures 85 in the first raster configuration 41.1. In this example, the first raster configuration 41.1 is a hexagonal raster with a raster pitch p1 of for example 100 μm.

FIG. 2B shows the origins of the secondary electron beamlets 9, formed by the focus spots 5 of the primary beamlets 3. At each irradiation position of a surface 25 of an object 7 with a primary charged particle beamlet 3, secondary electrons are generated, which form the plurality of secondary beamlets 9. The origins of the plurality of secondary beamlets 9 are therefore arranged in a second raster configuration 41.2, which is similar to the first raster configuration 41.1 of the primary charged particle beamlets 3. The second raster configuration 41.2 can be rotated with respect to the first raster configuration 41.1 and can have a different pitch of for example p2=10 μm.

FIG. 2C shows the focus points 15 of the secondary beamlets 9 in the image plane 225. During use, focus points 15 of the secondary beamlets 9 are formed in the image plane 225 of the secondary electron imaging system 200 in a third raster configuration 41.3. The third raster configuration 41.3 can be rotated with respect to the first and second raster configurations 41.1 and 41.2 and can have a third pitch of p3=1000 μm. The plurality of sets of detection elements 625 is arranged in a fourth raster configuration 41.4 (see FIG. 2D), which is ideally identical to the third raster configuration, i.e. with identical raster pitch p4=p3 and identical rotation angle. However, due to charging effects during an inspection operation, the third raster configuration 41.3 of focus spots 15 of secondary electron beamlets 9 might significantly deviate from the fourth raster configuration 41.4 of the sets of detection elements 625. Typically, the raster configurations are similar to each other. With the term “similar”, here a similarity according to the mathematical definition is used. “Similar” thus means related to each other by a scale transformation, a translation, a reflection, or by a rotation.

An example of a detector of the multi-beam charged particle imaging system 1 is illustrated in FIG. 3. The detector 600 comprises an electron-to-light conversion element 602, arranged in the image plane 225. The electron-to-light conversion element 602 is configured to convert the secondary electrons in the focus spots 15.1 to 15.3 of the secondary electron beamlets 9 into light. The detector further comprises an optical relay system with optical elements 605 and 611 for imaging and guiding the excited light from the electron-to-light conversion element 602 to detection elements 623. For that purpose, the optical relay system can comprise a zoom lens system 611, mirrors 607, rotating prisms (not shown) and light guiding fibers 615. In the example of FIG. 3, the detector 600 is configured to image the excited light from the electron-to-light conversion element 602 into an image plane 613, in which a plurality of entrance openings 613 of optical fibers 615 are arranged. The fourth raster configuration 41.4 is thereby defined by the arrangement of the entrance openings 613 of the optical fibers 615, and by the magnification by the optical system comprising lens 605 and zoom lens 611. The plurality of fiber ends 613 are fixed in a movable frame 617, which can be displaced or rotated. With zoom lens 611 or movable frame 617, a position and a rotation of the fourth raster configuration of entrance openings 613 of fibers 615, corresponding to the sets of detection elements 625, can be adjusted to the third raster configuration of focus points 15 formed in the image plane 225. Thereby, a maximum signal strength with a minimum cross talk is achieved.

The detector 600 further comprises a monitoring system 230 with a high-resolution detector 232 and an optical relay lens 235 of the monitoring system 230. The monitoring system 230 can optionally be retractable (indicated by retraction system 630) and/or can be coupled by a beam divider 237. The high-resolution detector 232 typically operates at a slow frame rate of for example about 10 to 20 frames per second and is thus not capable to collect the intensity signals at scanning speed of about 20M Hz to 80M Hz. The high-resolution detector 232 is however able to detect the raster configuration.

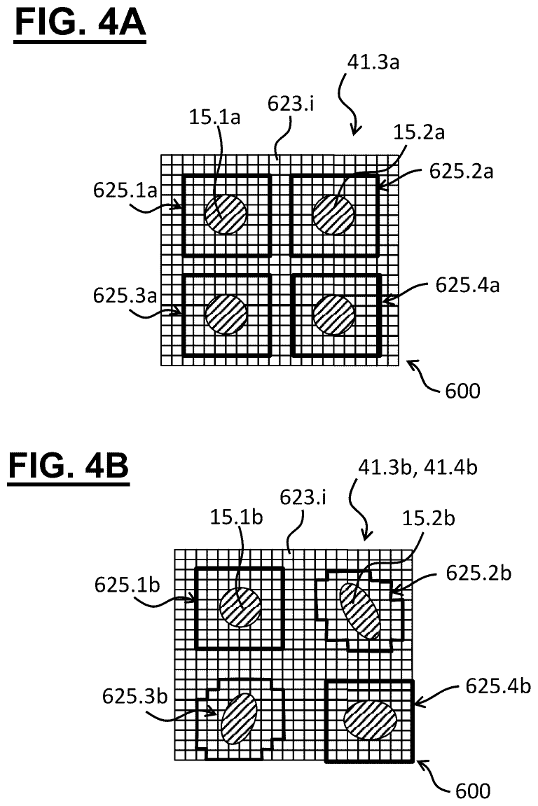

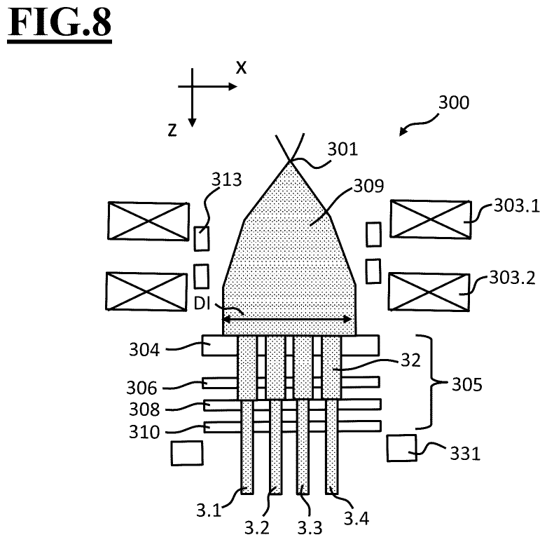

An alternative example of a detector 600 are illustrated in FIGS. 4A-4B. The detector 600 of this example comprises a plurality of detection elements 623 and a control mechanism to modify the assignment of the plurality of detection elements 623 to the sets of detections elements 625. Thereby, a modified fourth raster configuration 41.4b, formed by modified sets of detections elements 625b, is adjusted to a third raster configuration 41.3b of the focus spots 15b of the secondary electron beamlets 9. FIG. 8a shows a first raster configuration 41.3a of focus spots 15.1a to 15.4a. For example, the secondary electrons of the focus spot 15.1a are accumulated by the set of detection elements 625.1a, and the secondary electrons of the focus spot 15.2a are accumulated by the set of detection elements 625.2a. The first assignment of detection elements 623 to sets of detection elements 625.1a to 625.4a is initially determined and a high-speed readout circuitry is configured to accumulate and integrate over the detector signals of each detector 623 comprised in a set of detection elements 625. Such accumulation and integration is synchronized with a scanning speed of between 20M Hz to 80M Hz. Such high-speed integration can for example be achieved with embedded systems such as FPGAs. FIG. 8b shows a modified raster configuration 41.3b of focus spots 15.1b to 15.4b according to a sample charging. From each focus spot 15b, a modified set of detection elements 625.1b to 625.4b is determined and the modified assignment is used in a downstream inspection task. The modified set of detection elements 625b can not only be at different lateral position corresponding to the focus spots 15b but can also be of different shape or number of detection elements. Thereby, a shape deviation of a focus spot 15 can be considered as well. Thereby, a maximum signal strength with a minimum cross talk is achieved.

According to the first embodiment of the disclosure, the multi-beam charged particle imaging system 1 is configured for determining a minimum sample charging at high resolution imaging. Sample charging depends on several factors:
a) the deposited charge C
   The primary particle current I of a primary charge particle beamlet 3 and the dwell time T. The product of both defines the deposited charge Cd per pixel, which can be accumulated over a large scanning area.
b) the backscattered electron yield
   The backscattered electron yield SEY depends on the material composition of the sample.
c) the secondary electron yield SEY
   The secondary electron yield SEY depends on the material composition of the sample. The secondary electron yield SEY further depends on the kinetic energy of a primary charged particle beamlet 3. The kinetic beam energy of the primary charged particles 3—as they reach the sample surface 25—is determined by the extraction field generated by voltage supply unit 503. During irradiation, secondary electrons are generated, which may leave the sample and are extracted by the extraction field.
   Secondary and backscattered electrons reduce the deposited charge C to form a residual charge Cr.
d) discharge effects further reduce the residual charge Cr
   Fully conducting samples may not hold charges and the residual charge is instantly be reduced or distributed. Fully isolating samples may locally hold charges for longer time of for example seconds, and deposited charges are only reduced by thermal diffusion or leak currents at for example defects. Semiconductor sample may have spatially varying decay times between instant discharging of conductors connected to large capacities, slow discharging within seconds due to thermal diffusion in semiconductors, and even slower discharging effects in polymers such as photoresist or isolated memory cells.

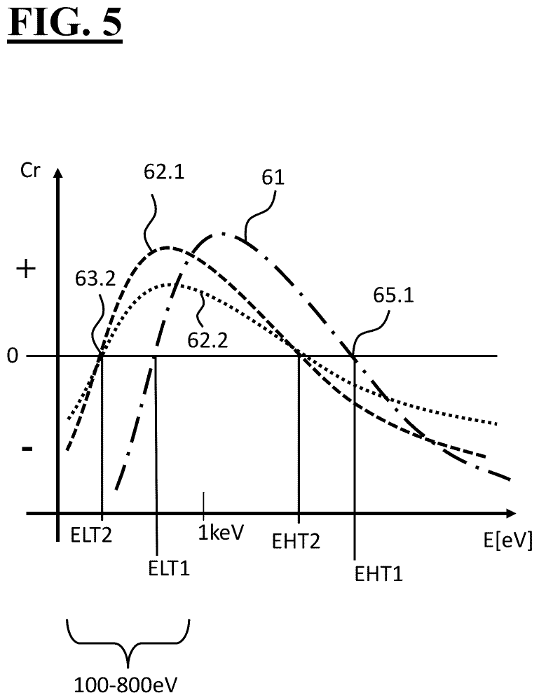

The secondary electron yield SEY is a function of the primary beam energy. The backscattered electron and secondary electron yield SEY and discharge effects depends on the material composition of the sample. FIG. 5 illustrates three examples of residual charging curves for different primary particle current or dwell times and different material compositions in dependence on the primary charged particle energy. The residual charge Cr of a first material composition with a first primary beam current 11 and a first dwell time t1 is illustrated with reference number 61. The residual charge curve 61 shows areas in which a sample is positively charged between the two kinetic energies ELT1 and EHT1, i.e. more secondary and backscattered electrons leave the sample compared to the deposited charge. The residual charge curve 61 shows areas where a sample is negatively charged at energies below ELT1 and above EHT 1, i.e. less secondary or backscattered electrons leave the sample compared to the deposited charge, leading to a negative charge accumulation in the sample. At the transition energies ELT and EHT, sample charging is minimized. A first minimum sample charging is achieved at a low kinetic energy ELT, corresponding to the low energy transition point ELT of no sample charging. The low energy transition point is depending on the material composition and is about below 800 eV, below 500 eV or even less. For example, for typical materials such as Cu, W, Al, Si, SiO₂ or SiN₂, comprised in semiconductor wafers, the low energy transition point is between 90 eV and 250 eV. A second minimum sample charging is achieved at a higher kinetic energy EHT, corresponding to the high energy transition point EHT of no sample charging. The high energy transition point EHT is depending on the material composition and is about above 1 kiloelectronvolt (keV), at a kinetic energy where a resolution of secondary electron imaging is generally limited by large interaction volumes exceeding several 10 nm. For example, the high energy transition point EHT of copper (Cu) or tungsten (W) is above 2 keV, where an imaging with high resolution is not possible anymore. A low kinetic energy transition point ELT is sometimes also called the instable neutral point. A high kinetic energy transition point EHT is sometimes also called the stable neutral point.

The second material composition has a residual charge Cr, a second primary beam current and a second dwell time. In an example, the second primary beam current is lower compared to a first beam current, and less deposited charge Cd is deposited. In an example, a second dwell time is larger compared to the first dwell time, and more charge is discharged during an inspection task.

Thus, by proper adjustment of the extraction field generated by voltage supply, a residual charging of a sample can be minimized. The multi-beam charged particle imaging system can be configured to operate at low kinetic energies ELT below 800 eV, which can typically not be achieved by conventional scanning electron microscopes. With the multi-beam charged particle imaging system it is therefore possible to generate by a voltage supply a strong extraction field between a wafer surface and objective lens, and thereby decelerate the primary electrons to below 800 eV, for example to 500 eV, 300 eV or even less, for example between 90 eV and 250 eV. With the same strong extraction field, secondary electrons of low kinetic energy of below 100 eV, for example only having 50 eV, are extracted and accelerated to be collected by the objective lens 102 and imaged by the detection unit 200 onto the imaging detector 600. The multi-beam charged particle imaging system 1 according to the first embodiment is therefore configured to perform a secondary electron imaging at higher resolution compared to a conventional scanning electron microscope, with interaction volumes below 15 nm, below 10 nm, or even less, for example 5 nm. The multi-beam charged particle imaging system 1 according to the first embodiment is configured to adjust the extraction field via the voltage supply 503 such that a charging of a specific material composition of an inspection target is minimized with kinetic beam energies of the primary charged particles close to a low energy transition point ELT. FIG. 5 shows the two low energy transition points ELT1 and ELT2 for the first and second material composition, respectively.

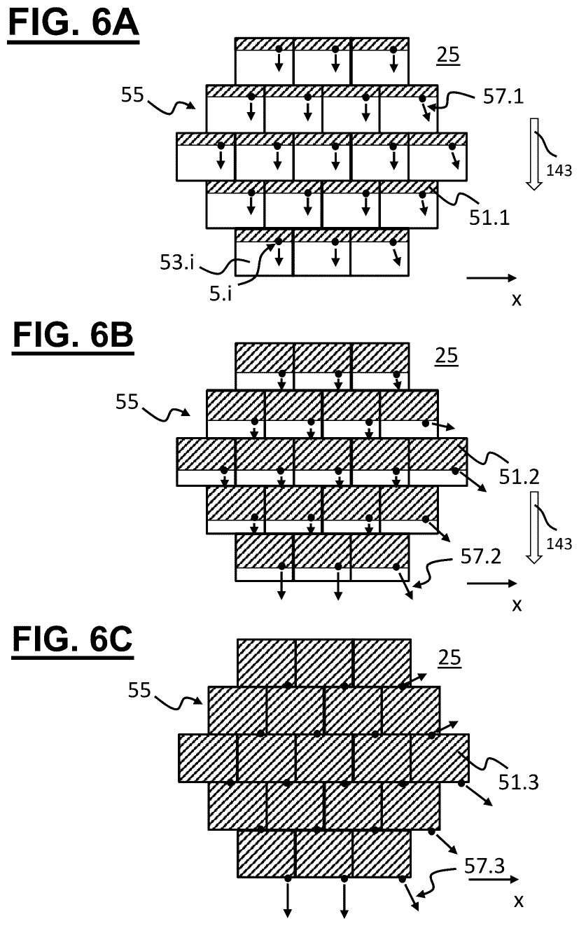

FIGS. 6A-6C illustrate the effects of a sample charging during an image acquisition with the multi-beam charged particle imaging system 1. The example illustrates an image acquisition with a sample charging, i.e. with imaging conditions deviation from the ideal kinetic energies E1 for high resolution and low sample charging. After an initial scanning of a few scanning lines in x-direction and acquisition of scanning image field segment 51.1 within each subfield 53.i with its corresponding primary charged particle focus spot 5.i, parts of the sample charge up and generate a large deflecting force in y-direction (illustrated by the arrows 57.1). The deflecting force 57.1 is generated in direction of the line scanning, illustrated by line scanning direction 143, perpendicular to the scanning lines in x-direction. After continued scanning, a larger part of the scanning image field segment 51.2 is acquired, and the larger parts of the sample surface are charged up. Thereby, the deflecting force 57.2 is reduced with exception of the beamlets at the boundary subfields, which experience an even increased deflecting force 57.2. After image acquisition is completed, a large deflection force 57.3 is generated at the boundaries, and the overall charged area of the image field 55 may generate a lens power to the primary and secondary beamlets.

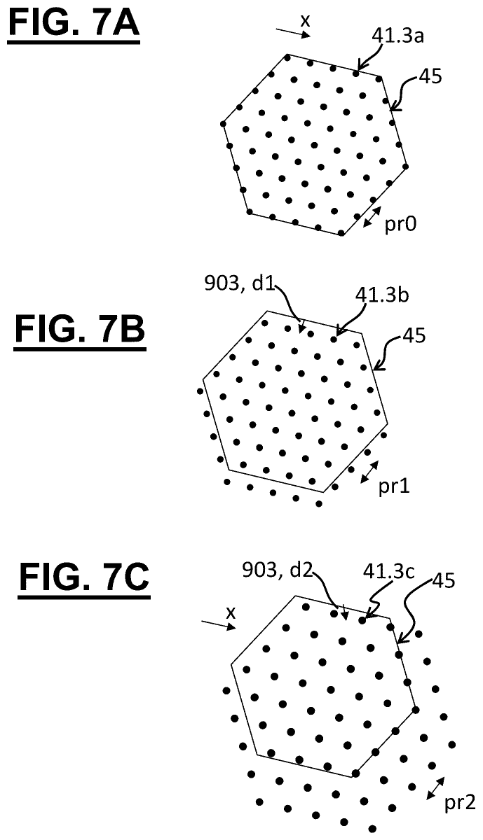

FIGS. 7A-7C illustrate some example of charging effects to the secondary electron beamlets, as detected by monitoring system 230 during an inspection task. FIG. 7A shows the raster configuration 41.3a of secondary electron focus spots in the image plane 225 at ideal imaging conditions, absent of any charging effects. FIG. 7B shows the effect of a sample charging comparable to FIG. 6B. FIG. 7C shows the effect of a sample charging comparable to FIG. 6C. With the monitoring system 230, a displacement (903) d1, d2 and a change in image pitch from pr0 to pr1 or pr2 can be detected and a presence of charging effect can be determined during image acquisition.

Thereby, the multi-beam charged particle imaging system 1 according to the first embodiment is configured to determine an optimized extraction field generated by the voltage supply 503 via the monitoring system 230 such that an effect of a sample charging is minimized.

In an example, semiconductor wafers are comprising different material compositions, where a sample charging cannot be completely avoided for each local material composition or structure. In such cases, the multi-beam charged particle imaging system 1 according to the first embodiment is configured to reduce a beam current and increase a dwell time. With reduced primary charged particle beam current, a deposited charge is reduced. With increased dwell time, the negative effects of a reduced primary charged particle beam current is compensated. With increased dwell time, an image acquisition time is increased and thus discharge effects have more time to decrease a residual sample charging by for example thermal diffusion. Thereby, unavoidable charging effects in varying local material compositions are at least reduced.

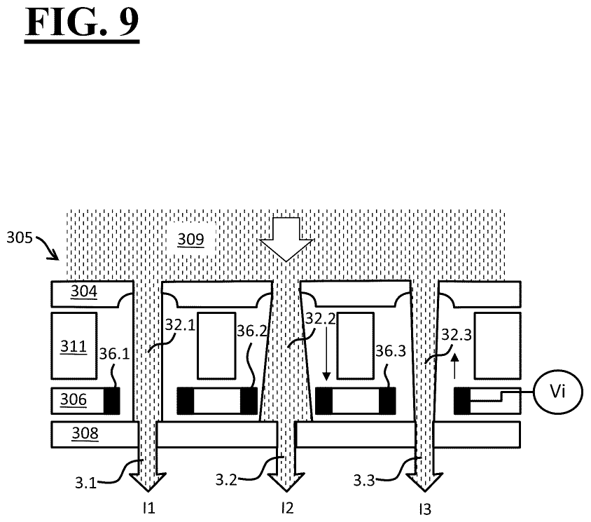

FIG. 8 shows an example of a primary beamlet generation unit 300 with a charged particle source 301 and a pair of collector lenses 303.1 and 303.2 for collimating the charged particle beam 309 generated by the charged particle source 301. The primary beamlet generation unit 300 further comprises deflection and correction multi-pole elements 313. The primary charged particle beam 309 is incident on a filter plate 304 with a plurality of apertures, for generating a first plurality of pre-shaped charged particle beamlets 32. The first plurality of pre-shaped charged particle beamlets 32 pass an active lens element 306 and are filtered by a second filter plate 308. The final primary charged particle beamlets 3.1 to 3.4 pass a further terminating multi aperture plate 310 and a field lens 331. By adjusting the lens powers of the collector lenses 303.1 and 303.2, or by adjusting a current provided to the source tip 301, a global adjustment of the charged particle beam current of the plurality of primary charged particle beamlets 3.1 to 3.4 can be adjusted. Each individual beam current of each individual primary charged particle beamlet 3 can further be adjusted by active lens element 306. This is further illustrated in FIG. 9 at an example. The pre-shaped beamlets 32.1 to 32.3 pass the apertures of an isolator 311 and are either focused or defocused by active lens element 306. For example, the first pre-shaped beamlet 32.1 is not changed and is filtered by the second filter plate 308 to a first beam current I1 for primary beamlet 3.1. The second pre-shaped beamlet 32.2 is defocused, and thus a lower second beam current I2<I1 is obtained for primary beamlet 3.2. The third pre-shaped beamlet 32.3 is focused, and thus a higher third beam current I3>I1 is obtained for primary beamlet 3.3. As illustrated above in conjunction with FIG. 5, the local charging of a material composition depends on the kinetic beam energy E and the beam current I. Reference is made again to FIG. 5. The secondary electron yield SEY depends on the kinetic beam energy E or the strength of the extraction field generated by voltage supply 503. At a low energy transition point ELT, the SEY is in balance with beam current, and no sample charging is effected. Below the low energy transition point ELT, less secondary electrons leave the sample, and a negative charge is generated. Above the low energy transition point ELT, more secondary electrons are generated and leave the sample surface, and a positive charge is generated at the surface of the sample. Especially in such a situation, a primary beam current can be reduced without an influence on the image noise generated at the transition point with E1.

For example, a first primary charged particle beamlet 3.1 is scanned over a first surface segment of a sample comprising the first material composition illustrated in residual charge curve 61. A secondary electron yield SEY 1 is in balance with the first beam current I1 of a first primary beamlet 3.1 at the first kinetic beam energy ELT1. The first beam current I1 has therefore no impact on a sample charging, but an impact on the secondary electron count, and thus the noise level within an image. The first beam current I1 and dwell time t1 is thus selected to collect enough secondary electrons to generate a certain maximum allowed noise level. A second primary charged particle beamlet 3.2, however, is scanned during operation over a different, second surface segment of a sample, with for example a different material composition, for example of the second material composition of charging curves 62.1, with a larger secondary electron yield SEY 2>SEY 1 at a kinetic beam energy ELT1. In such a situation, the beam current I3 can be reduced without increasing the noise level, and a charging in the second surface area is reduced. Therefore, by proper selection of the kinetic energy, in this example to the transition point of highest kinetic energy ELT1 within the low eV-and high-resolution range, and by reducing individual beam currents I2, a sample charging of a sample comprising different local material compositions or charging properties is minimized. This, a multi-beam charged particle system 1 according to an embodiment comprises a voltage supply 503, a primary beamlet generation unit 300 and a control unit 800, configured for variably adjusting a kinetic energy E of the plurality charged particle beamlets 3 with the voltage supply unit 503, and configured for variable adjusting an individual beam current I each of the plurality of primary charged particle beamlets 3 with the primary beamlet generation unit 300. In an example, the multi-beam charged particle system 1 further comprises a monitoring system 230 and a monitoring control unit 820, configured for monitoring during operation an effect of a sample charging on the focus spots 15 of the plurality of secondary electron beamlets 9. The control unit 800 is further configured to optimize the kinetic energy E and at least one individual beam current 12 during use of the multi-beam charged particle system 1.

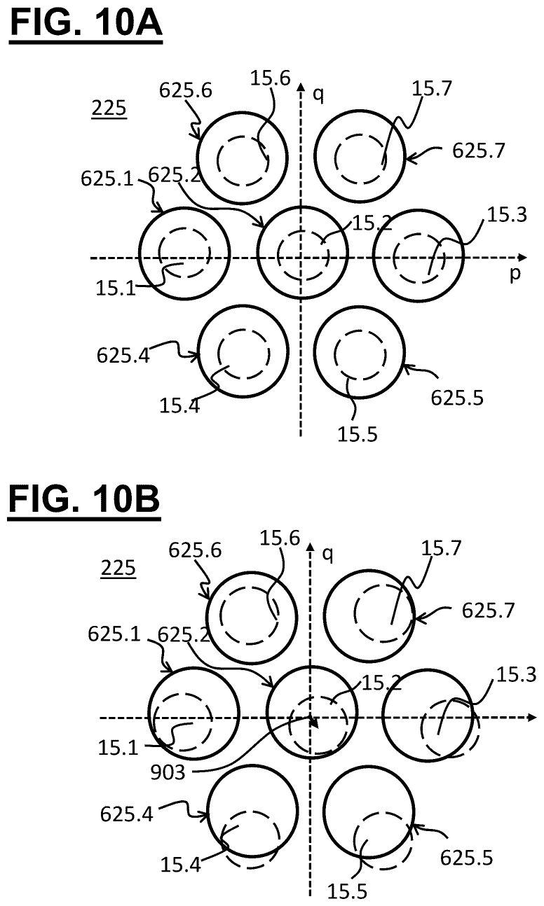

The monitoring systems 230 of the previous example are given by either a second electron detector or a second light detector 232 of FIG. 1 or 3. FIGS. 10A-10B illustrate a third example of a monitoring system 230. The third example is given by the secondary electron detector comprising a plurality of sets of detection elements 625 such as shown in FIGS. 4A-4B or FIGS. 10A-10B. After a sample charging, the plurality of focus spots 15.1 to 15.7 are displaced with respect to a plurality of sets of detection elements 625.1 to 625.7 by a displacement vector 903. The multi-beam charged particle imaging system 1 comprises the first deflection scanner 110, connected to the scanning control unit 860. During an inspection mode of operation, the scanning control unit 860 is configured to control the first deflection scanner 110 such that the plurality of primary charged particle beamlets 3 is scanned over the surface of a sample 7. Therefore, during the inspection mode of operation, a plurality of moving irradiation positions in a second raster configuration is formed on the surface of a sample 7. During an inspection mode, the origins of the secondary beamlets 9 are as well moving over time over the surface of the sample 7. The multi-beam charged particle imaging system 1 further comprises the second deflection scanner 222. During an inspection mode of operation, the scanning control unit 860 is configured to control the second deflection scanner 222 synchronous to the first deflection scanner 110. During an inspection mode of operation, the scanning control unit 860 is configured to control the second deflection scanner 222 with a deflection amplitude adjusted such that the focus spots 15 of the secondary electron beamlets 9 are kept within constant areas in the image plane 225 of the secondary electron imaging system 200. The constant areas correspond to areas formed by the sets of detection elements. An ideal situation is illustrated in FIG. 10A, where each of a plurality of focus spots 15.1 to 15.7 is centered at its corresponding set of detection elements 625.1 to 625.7. FIG. 10B illustrate the situation with a sample charging, where the plurality of focus spots 15.1 to 15.7 is decentered and shows a different pitch, similar to a situation illustrated in FIGS. 7B or 7C.

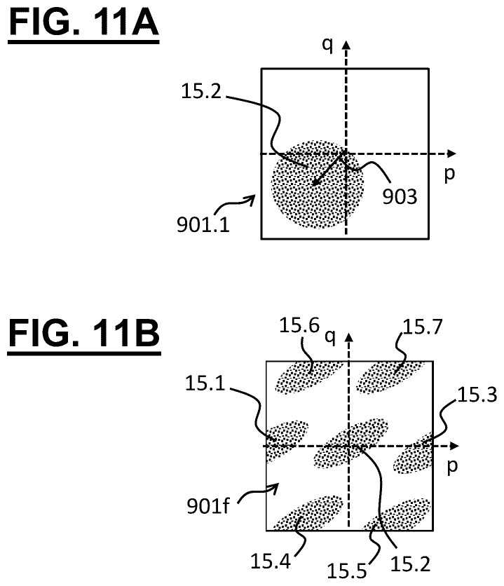

The multi-beam charged particle system 1 with the third example of a monitoring system 230 is configured for scanning the plurality of secondary electron beam spots 15 in parallel over the image plane 225 with scanning coordinates p and q. During a monitoring operation with the third example of a monitoring system 230, the plurality of focus spots 15 of the secondary beamlets 9 is scanned over the image plane 225 and a plurality of scanning intensity signals 901 is recorded over scan coordinates (p,q). From the stream of intensity signals 970 obtained from a set of detection elements, intensity signals are assigned to corresponding scanning coordinates (p,q) and the scanning intensity signals 901 are generated. Some examples of scanning intensity signals 901 are illustrated in FIGS. 11A-11B. FIG. 11A shows an example, where the focus spot 15.2 is decentered by a displacement vector 903. The scanning intensity signal 901.1 of FIG. 11A thus shows a decentered, intensity distribution of focus spot 15.2.

For illustration, the intensity distribution corresponding to a focus spot 15 in the image plane 225 is illustrated in FIGS. 11A-11B as a single, confined area. However, the focus spots 15 are more of for example a Gaussian shape with an inhomogeneous intensity distribution and a large extension, reaching for example over several sets of detection elements. Thereby, even in perfect alignment, some cross talk might be inevitable. The shape of each focus spots 15 in the scanning intensity signal 901 corresponds to a convolution of a focus spots 15 in image plane 225 with the area of the corresponding set of detection elements 625. This is simplified in FIG. 11A with an approximately circular area of each set of detection elements 625. The scanning intensity signals 901 corresponding to focus spots 15 in FIG. 11B merely illustrate the boundary of the focus spots 15 with an intensity threshold of for example 50% of the maximum intensity value applied. A multi-beam system 1 according to the first embodiment can further be configured for a determination of a shape of a focus spot 15 of a secondary electron beamlet 9. FIG. 11B illustrates an example, where the focus spot 15 of the plurality of secondary electron beamlets 9 have an elliptical shape. An elliptical shape of the focus spots 15 can for example arise from an astigmatism generated by a strong transition between two regions of different sample charging.

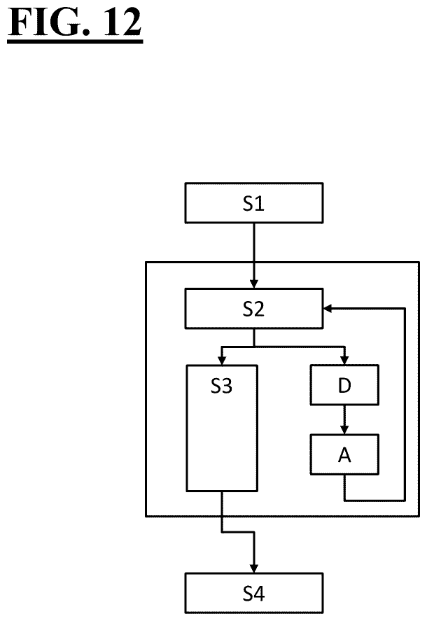

FIG. 12 illustrates an example of a method of operation of a multi-beam charged particle system with reduced sample charging according to a second embodiment.

In step S1, a wafer sample is placed at an inspection position in the image plane 101 of the multi-beam charged particle system 1.

In step S2, a first kinetic beam energy E1 of the plurality of primary charged particle beamlets 3 is adjusted by adjusting an extraction field between the wafer surface 25 and the objective lens 102 of the multi-beam charged particle system 1. Optionally, at least a first individual primary charged particle beam current I1 is individually adjusted such that it is different to a second individual primary charged particle beam current I2. Optionally, each of the first individual primary charged particle beam currents Ij are individually adjusted.

In step S3, an image acquisition of a surface of a sample is started.

In parallel step D, a plurality of focus spots 15 of the plurality of secondary electron beamlets 9 is monitored by monitoring system 230.

In parallel analysis step A, an effect of a surface charging on the plurality of focus spots 15 is analyzed and a correction of a first kinetic beam energy E1 to a second kinetic beam energy E2 is performed. For example, during the analysis step A, a displacement 903 and a scale or magnification error of the plurality of focus points 15 as illustrated in FIG. 7A-7C or FIG. 10A-10B is determined, and—depending on the scanning direction, it is determined whether a charging of a sample is positive or negative.

Optionally, a least a third individual primary charged particle beam current I3 is individually adjusted such that it is different to a first or second individual primary charged particle beam current I1 or I2.

In an example, method steps D and A are repeated several times during the image acquisition of step S3. In an example, method steps D and A are performed continuously during the image acquisition of step S3.

In an example, the image acquisition step S3 is a calibration operation, during which an optimal kinetic energy Eopt and optimal individual beam currents Iopt of the plurality of primary charged particle beamlets 3 are determined. The optimal kinetic energy Eopt and the optimal individual beam currents Iopt of the plurality of primary charged particle beamlets 3 are then stored in step S4 for repeated use at similar inspection sites of wafer samples.

The first kinetic beam energy E1 and the plurality of first individual primary charged particle beam currents Ij can be obtained from a previous calibration or from CAD information about the material composition of the sample. In a special application, a wafer sample is covered at least partially with photoresist, and the first kinetic beam energy E1 and the plurality of first individual primary charged particle beam currents Ij is adjusted to a wafer inspection for wafers covered with photoresist. In an example, the first kinetic beam energy E1 is adjusted to the maximum energy of a first low energy transition energy ELT1 of a first material composition and a second low energy transition energy ELT2 of a second material composition kinetic with E1=max[ELT1, ELT2]. In an example, E1 is equal to ELT1, and the beam current I2 of a primary charged particle beamlet 3.2 arranged to scan over the second material composition with the lower low energy transition energy ELT2 is reduced compared to I1 of a first beamlet 3.1.

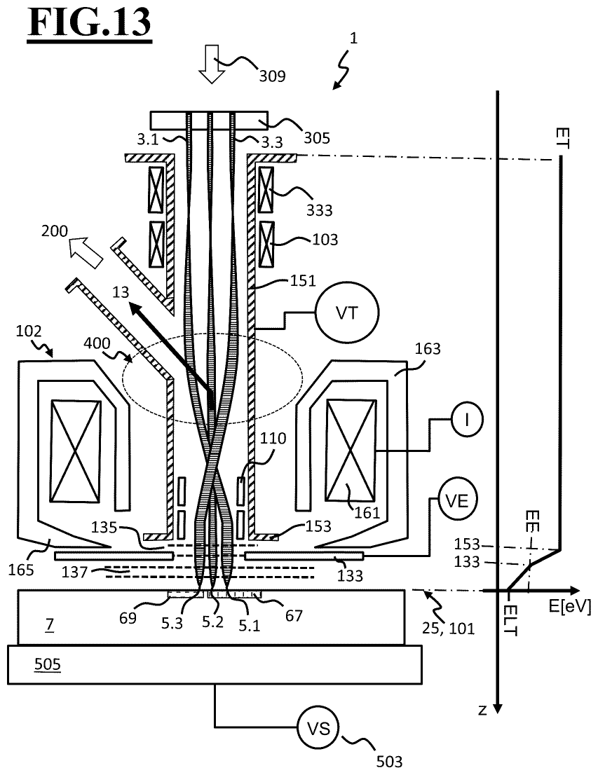

FIG. 13 illustrates some details of a multi-beam charged particle beam system 1 according to the first embodiment and illustrates further details of the method according to the second embodiment. From a collimated electron beam 309, a plurality of primary charged particle beamlets 3 is generated by the multi-aperture arrangement 305. For simplicity, only 3 beamlets 3.1 to 3.3 are shown, but there can be more beamlets, for example more than 60, more than 90, or even more than 300 beamlets. A beam tube 151 is provided downstream of the multi-aperture arrangement 305, the beam tube 151 being connected to a voltage supply with the first or tube voltage VT. From the entrance of a beam tube 151, the plurality of primary charged particle beamlets 3 is at a constant kinetic energy ET until the exit opening 153 of the beam tube 151. The kinetic energy ET of the primary charged particle beamlets 3 is for example 20K eV, 30K eV or more.

The plurality of primary charged particle beamlets 3 are imaged and focus points 5.1 to 5.3 are formed in an image plane 101 by field lenses 333 and 103, and by objective lens 102. The objective lens 102 is of the type of a magnetic lens with a coil 161 and a pole shoe 163 with a lower pole shoe segment 165, forming an axial gap for the magnetic field. A current I is provided during use to the coil 161 to generate the focusing magnetic field (not shown). Other types of magnetic lenses are possible as well, for example radial gap lenses for generation an immersion lens field, or magnetic lenses with several coils and pole shoes. Upstream or partially integrated in the objective lens 102, a beam divider 400 is arranged, configured to separate the secondary electrons along secondary electron beam path 13 to detector unit 200. Below the lower pole shoe segment 165, an electrode 133 is provided, connected to a voltage supply for providing a second voltage VE to the electrode. In the example shown, the electrode 133 is provided as separate electrode.

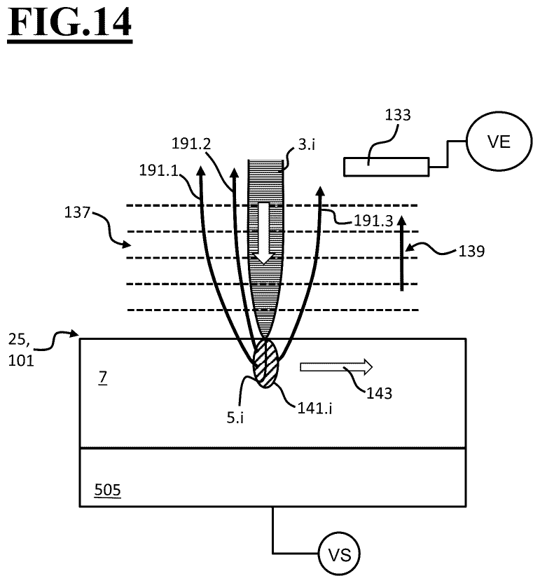

After leaving the beam tube 151, the plurality of primary charged particle beamlets 3 is decelerated from kinetic energy ET to a second kinetic energy EE. The voltage difference between VT and VE is responsible for the generation of a first electric field 135, illustrated in FIG. 13 with the equipotential lines of the first electric field 135. The first electrical field vectors are almost parallel to the propagation direction of the primary charged particle beamlets 3 and generate a decelerating force to the primary charged particles. The first voltage VE is typically adjusted such that the second kinetic energy EE is in a range below 5 keV, below 3 keV or even below 2 keV. Via sample voltage supple 503, a third sample voltage VS is provided to a sample mounting platform 505 for holding and contacting during use a wafer 7. At the surface 25 of the wafer 7, a first material composition 67 is arranged under a first set of primary charged particle beamlets 3.1 and 3.2, and a second material composition 69 is arranged under a second set of primary charged particle beamlet comprising primary charged particle beamlet 3.3. According to the voltage difference between VS and VE, a second electrical field 137 is generated, which is almost parallel to the propagation direction of the primary charged particle beamlets 3 and generates a decelerating force to the primary charged particles. The third or sample voltage VS is adjusted such that the third kinetic energy ELT is adjusted to a transition point according to a first or second material composition 67 or 69 in a range below 800 eV, below 300 eV or even below 100 eV (see FIG. 5 and description of FIG. 5). The electrical fields 135 and 137 both form a decelerating field to reduce the kinetic energy of the primary charged particle beamlets 3 before impinging on the sample surface 25 arranged in the image plane 101, such that the kinetic energy at the surface 25 is approximately corresponding to the low energy transition ELT of a material composition. The first electrical field 135 also forms an accelerating field on secondary electrons extracted from the wafer 7. The second electrical field 137 forms an extraction field for extracting and accelerating secondary electrons from the wafer 7. The second field 137 is therefore also called the extraction field 137. The extraction mechanism is further illustrated in FIG. 14. A primary charged particle beamlet 3.i is focused to focus point 5.i and impinges on the surface 25 of wafer 7 and forms an interaction volume 141.i in the wafer 7. During the operation at the low energy levels below 800 eV, below 300 eV or even below 100 eV, the interaction volume 141.i has a small extension below 5 nm or even less. The second or extraction field 137 extracts and accelerates secondary electrons generated in the interaction volume 141.i along electron trajectories (some example of electron trajectories 191.1 to 191.3 are shown) in opposite propagation direction to the primary electron beam direction.

The example illustrated in FIG. 13 shows a multi-beam charged particle beam system 1 with a two-stage deceleration field 135 and 137 and an additional electrode 133. In another example only a single decelerating or extraction field 137 is generated between exit aperture 153 of the beam tube 151 and a sample 7 mounted on the sample platform 505. In this case, the exit aperture 153 of the beam tube 151 has the role of the electrode 133 for the extraction field 137.

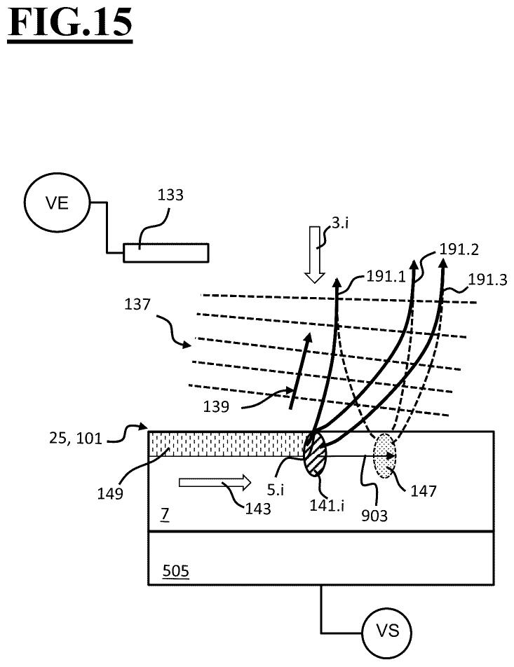

With the adjustment of the kinetic energy of the primary electron beamlets 3 approximately to a low energy transition energy ELT, the impinging electron beam current is in balance with the secondary electron beam current and a charging of a sample 7 is minimized. With “approximately to a low transition energy ELT” it is meant that the kinetic energy of the primary electron beamlets 3 deviates from an ideal low transition energy ELT of a material composition by less than 10%, for example by less than 7% or 5%. FIG. 15 illustrates the situation when a primary charged particle beamlet 3.i impinges on the sample surface with a kinetic energy deviating the low energy transition energy ELT of a material composition. The primary beamlet 3.i is scanned in scanning direction 143 and leaves a scanned surface segment 149 with a residual charge. This charging of the scanned surface segment 149 deteriorates the extraction field 137 generated between wafer sample 7 and electrode 133 and causes a local tilt to an extraction field vector 139. The effect of the extraction field vector 139 is more pronounced to the secondary electron beamlets 9 having a lower kinetic energy compared to the primary electrons of the impinging primary beamlet 3.1. Therefore, the secondary electron trajectories 191.1 to 191.3 are deflected more and a virtual interaction volume 147 appears with a lateral offset to the real interaction volume 141.i. As an effect, the virtual displacement of the virtual interaction volume 147 as virtual source of secondary electrons leads to a displacement 903 and magnification change of the focus points 15 of the raster of secondary electron beamlets 9 (see FIGS. 7A-7C). In FIG. 15, the effect of a negative charging is illustrated, with an additional vector component to the extraction field vector in positive line scanning direction 143. In an equivalent way, a positive charging would add a vector component to the extraction field vector in negative line scanning direction 143. In an example, from a displacement direction and the line scanning direction 143 perpendicular to the scanning lines, it is determined whether a positive or negative charging of a material composition of a structured wafer sample 7 occurs, and thereby it is determined whether the kinetic energy of the primary charged particles or has to be reduced or increased before reaching the sample surface 25. In an example, from a displacement direction and the line scanning direction 143 perpendicular to the scanning lines, it is determined that a positive charging of a material composition of a structured wafer sample 7 occurs, and a sample voltage VS is determined to reduce the first kinetic energy of the primary charged particles to a lower, second kinetic energy of the primary charged particles. In an example, from a displacement direction and the line scanning direction 143 perpendicular to the scanning lines, it is determined that a negative charging of a material composition of a structured wafer sample 7 occurs, and a sample voltage VS is determined to increase the first kinetic energy of the primary charged particles to a higher, second kinetic energy of the primary charged particles. The displacement direction of each secondary electron beamlet 9 can be determined during operation by the monitoring of the focus spots 15 of the secondary electron beamlets 7 with monitoring system 230.

A material composition can for example comprise isolating material, such as photoresist, silicon oxide or silicon nitride, or locally isolated conductors, which form local, isolated capacitances. Local isolated capacitances can comprise silicon, doped silicon, or metals.

With the method according to the second embodiment, it is possible to minimize a sample charging by selecting an optimized kinetic landing energy E1 of the plurality of primary charged particle beamlets 3 with the extraction field generated by sample voltage supply 503 of the multi-beam charged particle beam system 1. The effects of sample charging at improper selected kinetic landing energy E1 can be monitored with the monitoring system 230, and the extraction field generated by sample voltage supply 503 can be adjusted during use of the multi-beam charged particle beam system 1. Optimized or calibrated settings including the optimized kinetic energy Eopt of primary charge particle beamlets for minimized sample charging can be stored for later use at similar inspection positions or repeated inspection. In an example of a wafer sample with different material compositions at an inspection site of the multi-beam charged particle beam system 1, charging effects can further be reduced by reducing individual beam currents Iopt to reduce sample charging with no decrease of image quality or limited increase of image noise.

The disclosure is not restricted to the specific embodiments and examples, but variations of the embodiments are also possible. Although in principle reference is made to a wafer as an object, the disclosure is also applicable to other objects as used in semiconductor manufacturing. By way of example, the object can also be a mask, for example a mask for EUV lithography, rather than a semiconductor wafer. In contrast to semiconductor wafers, such masks are generally rectangular and have a significantly greater thickness. The disclosure is further described based on a multi-beam system having a plurality of primary electron beamlets, but other charged particles, for example helium ions, may also be used.

The disclosure is further described by following clauses:

Clause 1: A method of operating a multi-beam charged particle beam system (1), comprising
loading a sample on a sample platform (505) of a sample stage (500) of the multi-beam charged particle beam system (1), the sample (7) having a sample surface (25);
setting a first kinetic energy of the plurality of primary charged particle beamlets (3) before reaching the sample surface (25) by providing a first voltage via a voltage supply unit (503) to the sample platform (505), thereby generating an extraction field (137) between an objective lens (102) of the multi-beam charged particle beam system (1) and the sample surface (25);
starting an image acquisition of a surface segment of the sample surface (25);
monitoring a plurality of focus spots (15) of secondary electron beamlets (9), the secondary electron beamlets (9) being generated at a plurality of focus points (5) of the plurality of primary charged particle beamlets (3) at the sample surface (25);
determining at least one of a displacement or a scale error of the plurality of focus spots (15) of the secondary electron beamlets (9);
determining a second kinetic energy of the plurality of primary charged particle beamlets (3) from the displacement or the scale error, configured to minimize a charging effect of the sample (7);
setting the second kinetic energy by providing a second voltage to the sample platform (505).

Clause 2: The method according to clause 1, wherein the first or second kinetic energy of the plurality of primary charged particle beamlets (3) before reaching the sample surface (25) is set to a low energy of below 800 eV, for example below 500 eV, below 300 eV or even less.

Clause 3: The method according to clause 2, wherein the first or second kinetic energy of the plurality of primary charged particle beamlets (3) before reaching the sample surface (25) is set to a low energy between 90 eV and 250 eV.

Clause 4: The method according to clause 2, wherein the first or second kinetic energy of the plurality of primary charged particle beamlets (3) before reaching the sample surface (25) corresponds to a low energy transition energy ELT of a first material composition (67) at the sample surface (25).

Clause 5: The method according to clause 2, wherein the first or second kinetic energy of the plurality of primary charged particle beamlets (3) before reaching the sample surface (25) corresponds to a first low energy transition energy ELT1 of a first material composition (67) wherein a second low energy transition energy ELT2 of a second material composition (69) at the sample surface (25) is lower compared to the first low energy transition energy ELT1.

Clause 6: The method according to any of the clauses 1 to 5, further comprising individually reducing at least a beam current I of at least one of the plurality of primary charged-particle beamlets (3,3.1,3.2,3.3) configured for image acquisition of a surface segment comprising the second material composition (69).

Clause 7: The method according to any of the clauses 1 to 6, wherein the second kinetic energy is determined from the displacement error perpendicular to a line scanning direction (143) during image acquisition.

Clause 8: The method according to clause 7, wherein from a direction of the displacement error and the line scanning direction (143), a negative charging effect is determined, and a second kinetic energy is increased relative to the first kinetic energy.

Clause 9: The method according to clause 7, wherein from a direction of the displacement error and the line scanning direction (143), a positive charging effect is determined, and a second kinetic energy is reduced relative to the first kinetic energy.

Clause 10: The method according to any of the clauses 1 to 9, further comprising repeating monitoring and determining at least one of a displacement or a scale error of the plurality of focus spots (15) of the secondary electron beamlets (9) during an image acquisition and determining an optimized kinetic energy of the plurality of primary charged particle beamlets (3) configured to minimize a charging effect of the sample (7).

Clause 11: The method according to clause 10, further comprising storing the optimized kinetic energy in a memory (890) for repeated use at a sample (7) with similar material composition.

Clause 12: The method according to any of the clauses 1 to 11, wherein the first kinetic energy of the plurality of primary charged particle beamlets (3) before reaching the sample surface (25) is set according to a first material composition (67) of the sample surface (25).

Clause 13: The method according to any of the clauses 1 to 12, wherein the first kinetic energy of the plurality of primary charged particle beamlets (3) before reaching the sample surface (25) is set according to a previously determined kinetic energy stored in a memory (890).

Clause 14: A multi-beam charged particle beam system, comprising:
a primary beam illumination system (100) comprising a primary beamlet generation unit (300) and an objective lens (102);
a sample platform (505) connected to a sample voltage supply (503) configured to hold and contact a wafer (7) and to provide a sample voltage VS to a wafer (7);
at least an electrode selected from a group comprising an exit aperture (153) of a beam tube (151) and an electrode (133) connected to a voltage supply;
a control unit (800) configured to control the sample voltage supply (503) to provide a voltage VS to the sample platform (505) to effect a deceleration of primary charged particles before impacting on a surface (25) of a wafer (7) to a low energy transition energy ELT of a material composition of a wafer (7).

Clause 15: The multi-beam charged particle beam system (13) according to clause 14, further comprising a monitoring system (230) configured to monitor a plurality of focus spots (15) of a plurality of secondary electron beamlets (9), and a monitoring control unit (820) configured to determine during operation a displacement or scale error of the raster of focus spots (15) of secondary electron beamlets (9) obtained with the monitoring system (230).

Clause 16: The multi-beam charged particle beam system (13) according to clause 14 or 15, comprising a exit aperture (153) of a beam tube (151) connected to a voltage supply and an electrode (133) connected to a voltage supply, configured to generate a first, constant deceleration field (135) and a second, variable deceleration or extraction field (137) between the objective lens (102) and the surface (25).

Clause 17: A multi-beam charged particle beam system, comprising:
a primary beam illumination system (100) comprising a primary beamlet generation unit (300) and an objective lens (102);
a sample platform (505) connected to a sample voltage supply (503) configured to hold and contact a wafer (7) and to provide a sample voltage VS a wafer (7);
at least an electrode selected from a group comprising an exit aperture (153) of a beam tube (151) and an electrode (133) connected to a voltage supply;
a control unit (800) with a memory (890) comprising software instructions and a control processor (880) configured to execute the software instructions to perform a method according to any of the clauses 1 to 13.

Clause 18: The multi-beam charged particle beam system (13) according to clause 17, further comprising a monitoring system (230) configured to monitor a plurality of focus spots (15) of a plurality of secondary electron beamlets (9), and a monitoring control unit (820) configured to determine during operation a displacement or scale error of the raster of focus spots (15) of secondary electron beamlets (9) obtained with the monitoring system (230).

Clause 19: A method of wafer inspection with a multi-beam charged particle beam system (1), comprising
loading a wafer (7) on a sample platform (505) of a sample stage (500) of a multi-beam charged particle beam system (1), the wafer (7) having a wafer surface (25);
setting a first kinetic energy of the plurality of primary charged particle beamlets (3) before reaching the wafer surface (25) by adjusting an extraction field (137) between an objective lens (102) of the multi-beam charged particle beam system (1) and the sample surface (25);
starting an image acquisition of a surface segment of the wafer surface (25), wherein the first kinetic energy of the plurality of primary charged particle beamlets (3) before reaching the wafer surface (25) corresponds to a first low energy transition energy ELT of a first material composition (67) comprised within the surface segment of the wafer surface (25).

Clause 20: The method according to clause 19, wherein a second low energy transition energy ELT2 of a second material composition (69) comprised within the surface segment of the wafer surface (25) is lower compared to the first low energy transition energy ELT1.

Clause 21: The method according to any of the clause 20, further comprising individually reducing at least a beam current I of at least one of the plurality of primary charged-particle beamlets (3,3.1,3.2,3.3) configured for image acquisition of a surface segment comprising the second material composition (69).

Clause 22: The method according to any of the clauses 19 to 20, wherein the first kinetic energy of the plurality of primary charged particle beamlets (3) before reaching the wafer surface (25) is set to a low energy of below 800 eV, for example below 500 eV, below 300 eV or even less.

Clause 23: The method according to clause 22, wherein the first or second kinetic energy of the plurality of primary charged particle beamlets (3) before reaching the sample surface (25) is set to a low energy between 90 eV and 250 eV.

Clause 24: The method according to any of the clauses 19 to 23, wherein the first kinetic energy of the plurality of primary charged particle beamlets (3) before reaching the wafer surface (25) is set according to a previously determined kinetic energy stored in a memory (890).

Clause 25: The method according to any of the clauses 19 to 24, further comprising
monitoring a plurality of focus spots (15) of secondary electron beamlets (9), the secondary electron beamlets (9) being generated at a plurality of focus points (5) of the plurality of primary charged particle beamlets (3) at the sample surface (25);
determining at least one of a displacement or a scale error of the plurality of focus spots (15) of the secondary electron beamlets (9);
determining a second kinetic energy of the plurality of primary charged particle beamlets (3) from the displacement or the scale error, configured to minimize a charging effect of the sample (7);
setting the second kinetic energy by providing a second voltage to the sample platform (505).

Clause 26: The method according to clause 25, wherein the second kinetic energy is determined from the displacement error perpendicular to a line scanning direction (143) during image acquisition.

Clause 27: The method according to clause 26, wherein from a direction of the displacement error and the line scanning direction (143), a negative charging effect is determined, and a second kinetic energy is increased relative to the first kinetic energy.

Clause 28: The method according to clause 26, wherein from a direction of the displacement error and the line scanning direction (143), a positive charging effect is determined, and a second kinetic energy is reduced relative to the first kinetic energy.

Clause 29: The method according to any of the clauses 25 to 28, further comprising repeating monitoring and determining at least one of a displacement or a scale error of the plurality of focus spots (15) of the secondary electron beamlets (9) during an image acquisition and determining an optimized kinetic energy of the plurality of primary charged particle beamlets (3) configured to minimize a charging effect of the sample (7).

Clause 30: The method according to any of the clauses 19 to 29, wherein adjusting the extraction field (137) between an objective lens (102) of the multi-beam charged particle beam system (1) and the sample surface (25) comprises a step of providing a voltage VS via a voltage supply unit (503) to the sample platform (505).

A method for imaging of semiconductor samples with reduced charging effects and a multi-beam charged particle beam system configured for imaging of semiconductor samples with reduced charging effects is provided. The reduced charging effect is achieved by adjusting the kinetic energy of primary charged particles to a low energy transition energy, where charging of a material composition is minimized. The system and method include for example a monitoring system and optimization of the kinetic energy to minimize charging effects.

A list of reference signs is provided:
1 Multi-beam charged particle system
3 primary beamlets
5 focus point of primary beamlets in object plane
7 sample or object
9 secondary electron beamlets
15 focus point of secondary electron beamlets in image plane
25 surface of object
27 structure
32 pre-shaped beamlets
36 lens electrodes
41 Raster configuration
45 frame of ideal raster configuration
47 frame of ideal raster configuration
51 scanned area
53 subfield
55 image field
59 deflection force
61 charging curve for first material composition
62 charging curve for second material composition
63 instable neutral point
65 stable neutral point
67 first material composition
69 second material composition
85 apertures
100 primary beam illumination system
101 object plane
102 objective lens
103 field lenses
108 intersection point
110 first scanning deflector
133 electrode
135 deceleration field (equipotential lines)
137 extraction field (equipotential lines)
139 force vector
141 interaction volume
142 scanning direction
143 scanning direction
147 virtual interaction volume
149 charged area
151 beam tube
153 lower end of beam tube 151
161 coil
163 pole piece
165 lower pole piece section
191 secondary electron trajectory
200 secondary electron imaging system
205 imaging lenses
216 multi-aperture array element
222 second scanning deflector
225 Image plane
230 monitoring system
232 monitoring detector
235 monitoring relay lens
237 monitoring deflector or divider
300 primary beamlet generation unit
301 charged particle source
303 Collector lenses
304 filter plate
305 multi-aperture arrangement
306 multi-aperture plate
309 collimated charged particle beam
310 terminating multi-aperture plate
313 deflection and correction multi-pole elements
321 intermediate image surface
331 Field lens
333 Field lens
400 beam divider
500 Sample stage
503 voltage supply for extraction field
505 sample mounting platform
600 detector
602 electron to light converter
605 optical imaging element
607 folding mirror
609 light beam
611 optical zoom
613 image plane of optical relay
615 optical light guide
617 light guide frame
623 detection element
625 set of detection elements
630 retraction system
800 control unit
810 image data acquisition unit
820 monitoring control unit
830 primary beamlet control module
840 Adjustment control unit
860 Scanning control unit
880 control processor
890 memory
901 scanning image
903 displacement vector
907 intensity signal

What is claimed is:

1. A method of operating a multi-beam charged particle beam system comprising a sample on a sample platform of a sample stage of the multi-beam charged particle beam system, the sample comprising a sample surface, the method comprising:
setting a first kinetic energy of a plurality of primary charged particle beamlets before reaching the sample surface by providing a first voltage via to the sample platform to generate an extraction field between an objective lens of the multi-beam charged particle beam system and the sample surface, the plurality of primary charged particle beamlets generated by the multi-beam charged particle beam system;
starting an image acquisition of a surface segment of the sample surface;
monitoring a plurality of focus spots of secondary electron beamlets generated at a plurality of focus points of the plurality of primary charged particle beamlets at the sample surface;
determining a displacement or a scale error of the plurality of focus spots of the secondary electron beamlets;
determining a second kinetic energy of the plurality of primary charged particle beamlets from the displacement or the scale error, to reduce a charging effect of the sample;
setting the second kinetic energy by providing a second voltage to the sample platform.

2. The method of claim 1, wherein a member selected from the group consisting of the first kinetic energy and the second kinetic energy is less than 800 electronvolts.

3. The method of claim 1, wherein a member selected from the group consisting of the first kinetic energy and the second kinetic energy is between 90 electronvolts (eV) and 250 eV.

4. The method according to claim 1, wherein a member selected from the group consisting of the first kinetic energy and the second kinetic energy corresponds to a low energy transition energy of a first material composition at the sample surface.

5. The method according to claim 1, wherein a member selected from the group consisting of the first kinetic energy and the second kinetic energy corresponds to a low energy transition energy of a first material composition at the sample surface, and a low energy transition energy of a second material composition at the sample surface is less than the first low energy transition energy.

6. The method of claim 5, further comprising individually reducing a beam current of at least one of the plurality of primary charged-particle beamlets configured for image acquisition of a surface segment comprising the second material composition.

7. The method of claim 1, comprising determining the second kinetic energy from the displacement error perpendicular to a line scanning direction during image acquisition.

8. The method of claim 7, further comprising:
determining a negative charging effect from a direction of the displacement error and the line scanning direction; and
increasing the second kinetic energy relative to the first kinetic energy.

9. The method of claim 7, further comprising:
determining a positive charging effect from a direction of the displacement error and the line scanning direction; and
reducing the second kinetic energy relative to the first kinetic energy.

10. The method of claim 1, further comprising:
repeating the monitoring and the determining during an image acquisition; and
determining an optimized kinetic energy of the plurality of primary charged particle beamlets configured to reduce the charging effect of the sample.

11. The method of claim 10, further comprising storing the optimized kinetic energy in a memory.

12. The method of claim 1, wherein the first kinetic energy is set according to a first material composition of the sample surface.

13. The method of claim 1, wherein the first kinetic energy is set according to a previously determined kinetic energy.

14. One or more machine-readable hardware storage devices comprising instructions that re executable by one or more processing device to perform operations comprising the method of claim 1.

15. A system, comprising:
one or more processing devices; and
one or more machine-readable hardware storage devices comprising instructions that re executable by one or more processing device to perform operations comprising the method of claim 1.

16. The system of claim 15, further comprising:
a primary beam illumination system comprising a primary beamlet generation unit and an objective lens;
a sample platform configured to hold an object;
a voltage supply connected to the sample platform to provide a voltage to the object;
an electrode connected to the voltage supply, the electrode being selected from the group consisting of an exit aperture electrode and a beam tube electrode; and
a controller configured to control the voltage supply to provide the voltage to the sample platform to decelerate primary charged particles before impacting on a surface of a wafer the wafer so that the primary charged particles impact the surface of the object at a low energy transition energy a material composition of the object.

17. The system of claim 16, further comprising:
a monitor system configured to monitor focus spots of secondary electron beamlets; and
a monitoring controller configured to determine a displacement or scale error of a raster of focus spots of the secondary electron beamlets obtained via the monitoring system.

18. A multi-beam charged particle beam system, comprising:
a primary beam illumination system comprising a primary beamlet generation unit and an objective lens;
a sample platform configured to hold an object;
a voltage supply connected to the sample platform to provide a voltage to the object;
an electrode connected to the voltage supply, the electrode being selected from the group consisting of an exit aperture electrode and a beam tube electrode; and
a controller configured to control the voltage supply to provide the voltage to the sample platform to decelerate primary charged particles before impacting on a surface of a wafer the wafer so that the primary charged particles impact the surface of the object at a low energy transition energy a material composition of the object.

19. The multi-beam charged particle beam system of claim 18, further comprising:
a monitor system configured to monitor focus spots of secondary electron beamlets; and
a monitoring controller configured to determine a displacement or scale error of a raster of focus spots of the secondary electron beamlets obtained via the monitoring system.

20. The multi-beam charged particle beam system of claim 18, comprising an exit aperture of a beam tube connected to a voltage supply, and an electrode connected to a voltage supply, wherein the electrode is configured to generate a first, constant deceleration field and a second, variable deceleration or extraction field between the objective lens and the surface of the object.
